(19) United States
(12) Patent Application Publication
(10) Pub. No.: US 2006/0105199 A1
(43) Pub. Date: May 18, 2006

(54) Electroluminescent devices containing trans-1,2-bis(acenyl)ethylene compounds

(75) Inventors: Christopher P. Gerlach, St. Paul, MN (US); Fred B. McCormick, Maplewood, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 10/991,561

(22) Filed: Nov. 18, 2004

(51) Int. Cl. H01L 51/54; H05B 33/14

(52) U.S. Cl. 428/690; 428/917; 313/504; 313/506; 427/66

(57) ABSTRACT

Organic electroluminescent devices and methods of making organic electroluminescent devices are described. The organic electroluminescent devices include an organic emissive element that is positioned between two electrodes. The organic emissive element contains a trans-1,2-bis(acenyl)ethylene compound where the acenyl group is selected from 2-naphthyl, 2-anthracenyl, or 2-tetracenyl.

### TECHNICAL FIELD

The present invention provides organic electroluminescent devices and methods of making organic electroluminescent devices that include an organic emissive element that contains a trans-1,2-bis(acenyl)ethylene compound.

### BACKGROUND

Organic electroluminescent devices such as organic light emitting diodes (OLEDs) are desirable for use in various electronic media based on properties such as their thin profile, low weight, capability of emitting a variety of colors, and low driving voltage. OLEDs have potential use in various applications such as backlighting of graphics, pixelated displays, solid-state lighting, photovoltaics, and large emissive graphics.

OLEDs contain at least one electroluminescent material, a material that is capable of emitting light (e.g., light in the visible range of the electromagnetic spectrum) when electrically activated. A variety of electroluminescent materials are known that include, for example, small molecule emitters, polymers doped with small molecule emitters, light emitting polymers, light emitting polymers doped with small molecule emitters, and blends of light emitting polymers.

There is continuing research aimed at developing other electroluminescent materials. For example, there is a continuing need for electroluminescent materials that emit blue light.

### SUMMARY

Organic electroluminescent devices and methods of making the organic electroluminescent devices are provided. More specifically, the organic electroluminescent devices include an organic emissive element that contains at least one trans-1,2-bis(acenyl)ethylene compound.

In one aspect, organic electroluminescent devices are provided that include two electrodes and an organic emissive element positioned between the two electrodes. The organic emissive element contains a trans-1,2-bis(acenyl)ethylene compound of Formula I. 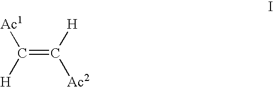
In Formula I, each Ac¹ and Ac² is independently an unsubstituted or substituted 2-acenyl selected from 2-naphthyl, 2-anthracenyl, or 2-tetracenyl. A substituted 2-acenyl group can have at least one substituent selected from an alkyl, alkoxy, alkylthio, halo, haloalkyl, or a combination thereof.

In another aspect, a method of preparing an organic electroluminescent device is provided. The method involves preparing an organic emissive element that contains a trans-1,2-bis(acenyl)ethylene compound of Formula I; and positioning the organic emissive element between two electrodes.

The above summary of the present invention is not intended to describe each disclosed embodiment or every implementation of the present invention. The Figures, Detailed Description, and Examples that follow more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 is a schematic side view of an organic electroluminescent display construction.

FIG. 2 is a schematic side view of an exemplary organic electroluminescent display.

FIGS. 3A to 3D are schematic side views of four embodiments of organic electroluminescent devices.

FIG. 4 is a plot showing the weight loss of trans-1,2-bis(2-anthracenyl)ethylene as a function of temperature.

FIG. 5 shows the X-ray diffraction pattern of trans-1,2-bis(2-antracenyl)ethylene vapor deposited on a poly(alpha-methylstyrene)-treated SiO₂ substrate.

FIG. 6 shows the optical spectra (i.e., ultraviolet-visible and fluorescence) for trans-1,2-bis(2-anthracenyl)ethylene.

FIG. 7 shows a plot of light intensity versus wavelength for an OLED containing trans-1,2-bi s(2-anthracenyl)ethylene.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION OF THE INVENTION

The present invention provides organic electroluminescent devices and methods of preparing organic electroluminescent devices that include an organic emissive element that contains a trans-1,2-bis(acenyl)ethylene compound. Suitable acenyl groups include those having 2 to 4 fused benzene rings.

### DEFINITION

As used herein, the terms “a”, “an”, and “the” are used interchangeably with “at least one” to mean one or more of the elements being described.

As used herein, the term “acene” refers to a polycyclic aromatic hydrocarbon group having at least 2 fused benzene rings in a rectilinear arrangement as shown by the following formula where n is an integer equal to or greater than zero. 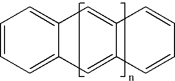
The acene usually has 2 to 4 fused benzene rings.

As used herein, the term “acenyl” refers to a monovalent group that is a radical of an acene. The acenyl group usually has 2 to 4 fused benzene rings in a rectilinear arrangement. Exemplary acenyl groups include naphthyl, anthracenyl, and tetracenyl.

As used herein, the term “alkyl” refers to a monovalent group that is a radical of an alkane. The alkyl can be linear, branched, cyclic, or combinations thereof and typically contains 1 to 30 carbon atoms. In some embodiments, the alkyl group contains 1 to 20, 1 to 14, 1 to 10, 4 to 10, 4 to 8, 1 to 6, or 1 to 4 carbon atoms. Examples of alkyl groups include, but are not limited to, methyl, ethyl, n-propyl, isopropyl, n-butyl, tert-butyl, isobutyl, n-pentyl, n-hexyl, cyclohexyl, n-octyl, n-heptyl, and ethylhexyl.

As used herein, the term “alkoxy” refers to a monovalent group of formula —OR where R is an alkyl group. Examples of alkoxy groups include methoxy, ethoxy, propoxy, butoxy, and the like.

As used herein, the term “halo” refers to a halogen group (i.e., F, Cl, Br, or I).

As used herein, the term “haloalkyl” refers to an alkyl group having a halo substituent.

As used herein, the term “alkylthio” refers to a monovalent group of formula —SR where R is an alkyl group.

Organic Electroluminescent Devices

Organic electroluminescent devices such as organic light emitting diodes include an organic emissive element positioned between two electrodes (i.e., an anode and a cathode). The organic emissive element contains at least one electroluminescent material. Additionally, the organic emissive element can include other optional materials such as, for example, charge transport materials, charge blocking materials, charge injection materials, color conversion materials, buffer materials, or a combination thereof.

Organic light emitting diodes are often arranged in the following order: anode, a hole transport layer, light emitting layer, electron transport layer, and cathode. Electrons are injected into the electron transporting layer from the cathode and holes are injected into the hole transporting layer from the anode. The charge carriers migrate to the light emitting layer where they combine to emit light. At least one of the electrodes is usually transparent (i.e., the light can be emitted through the transparent electrode).

This invention provides an organic electroluminescent device that includes two electrodes and an organic emissive element positioned between the two electrodes. The organic emissive element contains a trans-1,2-bis(acenyl)ethylene compound of Formula I. 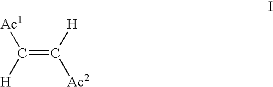
In Formula I, Ac¹ and Ac² are each independently an unsubstituted or substituted 2-acenyl selected from 2-naphthyl, 2-anthracenyl, or 2-tetracenyl. A substituted 2-acenyl group has at least one substituent selected from an alkyl, alkoxy, alkylthio, halo, haloalkyl, or a combination thereof (i.e., the compound can have multiple substitutents).

The Ac¹ and Ac² groups in Formula I can be an unsubstituted or substituted 2-acenyl group having 2 to 4 fused benzene rings arranged in a rectilinear arrangement. These two groups can be the same or different. For example, the Ac¹ group can be 2-naphthyl and the Ac group can be selected from 2-naphthyl, 2-anthracenyl, or 2-tetracenyl. In another example, the Ac¹ group can be 2-anthracenyl and the Ac2 group can be selected from 2-anthracenyl or 2-tetracenyl. In yet another example, both of the Ac¹ and the Ac² group can be 2-tetracenyl.

The Ac¹ and Ac² groups can independently be unsubstituted or substituted with an alkyl, alkylthio, halo, haloalkyl, or combinations thereof. In some compounds according to Formula I, both the Ac¹ and the Ac² groups are unsubstituted. In other compounds according to Formula I, Ac¹ is unsubstituted and Ac² is substituted. In still other compounds according to Formula I, both Ac¹ and Ac² are substituted. A substituent can be located at any position on the acenyl group other than the 2-position. The substituents can often improve the compatibility of the trans-1,2-bis(2-acenyl)ethylene compounds with various coating compositions.

Compounds with fused aromatic ring systems are commonly given a numbering sequence in which each carbon atom that is a member of only one ring is numbered. The various positions of 2-acenyl groups are shown in the following formulas for 2-naphthyl, 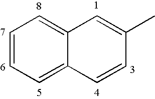
2-anthracenyl,

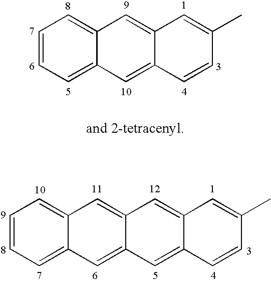

Some exemplary compounds according to Formula I have a substituent that is located on a benzene ring that is not adjacent to the ethylene group (i.e., the substituent is not in the 1-position, 3-position, or 4-position). For example, the substituent can be located on a benzene ring that is furthest from the 2-position. A 2-naphthyl or a 2-anthracenyl is substituted at the 5-position, 6-position, 7-postion, or 8-position; or a 2-tetracenyl is substituted at the 7-position, 8-position, 9-position, or 10-position. Some compounds are substituted in multiple positions.

In some organic emissive elements, the compound according to Formula I is selected from an unsubstituted or substituted trans-1,2-bis(2-naphthyl)ethylene; unsubstituted or substituted trans-1,2-bis(2-anthracenyl)ethylene; or unsubstituted or substituted trans-1,2-bis(2-tetracenyl)ethylene. Some exemplary semiconductor layers contain trans-1,2-bis(2-anthracenyl)ethylene or trans-1,2-bis(2-tetracenyl)ethylene that is unsubstituted or substituted with one or more substituents selected from alkyl, alkoxy, alkylthio, halo, haloalkyl, or a combination thereof.

The trans-1,2-bis(2-acenyl)ethylene compounds tend to form predominately one crystalline phase. For example, the compounds tend to have less than 10 weight percent, less than 5 weight percent, less than 2 weight percent, or less than 1 weight percent of a second crystalline phase.

Trans-1,2-bis(2-acenyl)ethylene compounds with identical acenyl groups can be prepared according to Reaction Scheme A by a Stille coupling reaction. A 2-halo-acene (i.e., Formula II where Ac is an acenyl group and X is a halo group) such as 2-chloro-acene or 2-bromo-acene can be reacted with a bis(trialkylstannyl)ethylene (i.e., Formula III where R is an alkyl group) to form a trans-1,2-bis(2-acenyl)ethylene (i.e., Formula IV). The Stille coupling reaction is further described, for example, in A. F. Littke et al., J. American Chem Soc., 124(22), 6343-6348 (2002). The reaction product Formula IV can be purified by any known process such as by vacuum sublimation.

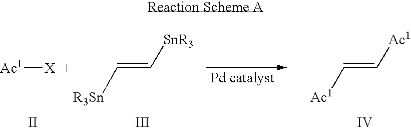

Other synthetic approaches can be used to prepare trans-1,2-bis(2-acenyl)ethylene compounds. For example, trans-1,2-bis(2-anthracenyl)ethylene can be prepared by reducing 1,2-bis(2-anthraquinoyl)ethylene as described in B. Becker et al., J. Am. Chem. Soc., 113, 1121-1127 (1991). Alternatively, trans-1,2-bis(2-anthracenyl)ethylene can be prepared using the Wittig reaction of 2-anthracenyltriphenylphosphonium bromide and anthracene-2-carbaldehyde as described in Karatsu et al., Chemistry Letters, 1232-1233 (2001). Other trans-1,2-bis(acenyl)ethylene compounds can be prepared using similar reactions.

Trans-bis(2-acenyl)ethylene compounds having at least one substituent can be prepared by a Stille coupling of a ring-substituted 2-halo-acene (e.g., a ring-substituted 2-bromo-acene or a ring-substituted 2-chloro-acene) with a bis(trialkylstannyl)ethylene. Suitable ring-substituted 2-halo-acenes include, for example, ring-substituted 2-halo-naphthalene, ring-substituted 2-halo-anthracene, or ring-substituted 2-halo-tetracene where the halo is bromo or chloro. The ring-substituted 2-halo-acenes can be prepared by methods known in the art, and reference may be made to the synthetic schemes described in U.S. patent application Nos. 20030105365; U.S. patent application Ser. No. 10/620,027 filed on Jul. 15, 2003; and U.S. patent application Ser. No. 10/641,730 filed on Aug. 15, 2003.

Asymmetric trans-1,2-bis(acenyl)ethylene (i.e., a compound with different acenyl groups such as Formula IX) can be prepared, for example, through the use of coupling reactions such as the Wittig reaction as shown in Reaction Scheme B and further described, for example, in Trippett, Quart. Rev., 17, 406 (1963). An acene substituted with an alkyl bromide (i.e., Formula V) can be reacted with triphenylphosphine to form a triphenylphosphonium salt (i.e., Formula VI). Exposure to a base forms the “ylide” (i.e., Formula VII) which can then react with an acene-2carbaldehyde (i.e., Formula VIII) to form triphenylphosphonium oxide and the asymmetric trans-1,2-bis(2-acenyl)ethylene (i.e., Formula IX). As used herein, the term “asymmetric trans-1,2-bis(2-acenyl)ethylene compounds” refers to compounds of Formula I where Ac¹ is different than Ac².

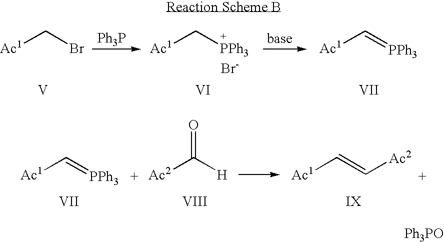

The organic emissive element of an organic electroluminescent device usually includes at least one light emitting layer. Other layers can also be present in the organic emissive element such as hole transport layers, electron transport layers, hole injection layers, electron injection layers, hole blocking layers, electron blocking layers, buffer layers, and the like. In addition, photoluminescent materials can be present in the light emitting layer or other layers in OEL devices, for example, to convert the color of light emitted by the electroluminescent material to another color. These and other such layers and materials can be used to alter or tune the electronic properties and behavior of the layered OEL device. For example, the additional layers can be used to achieve a desired current/voltage response, a desired device efficiency, a desired color, a desired brightness, and the like.

The trans-1,2-bis(acenyl)ethylene compound can be included in one or more layers of an organic emissive element that contains multiple layers. For example, the trans-1,2-bis(acenyl)ethylene compound can be in a light emitting layer, a charge transfer layer (e.g., a hole transport layer), or a combination thereof. Within any layer, the trans-1,2-bis(acenyl)ethylene compound may be present alone or in combination with other materials. For example, the trans-1,2-bis(acenyl)ethylene compound can function as a dopant or as a host material within a light emitting layer of the organic emissive element.

In some organic emissive elements, the trans-1,2-bis(acenyl)ethylene compound is present in a light emitting layer. The trans-1,2-bis(acenyl)ethylene compound can be used alone or in combination with one or more materials in the light emitting layer. For example, the trans-1,2-bis(acenyl)ethylene compound can be a dopant in a light emitting layer. As used herein, the term “dopant” refers to a material that is capable of being excited by a transfer of energy from a host material. The excited dopant emits light. The dopant is typically present in an amount less than 50 weight percent, less than 40 weight percent, less than 20 weight percent, less than 10 weight percent, or less than 5 based on the weight of material in the light emitting layer. The dopant is typically present in an amount of at least 0.1 weight percent, 0.2 weight percent, 0.5 weight percent, or 1 weight percent based on the weight of material in the light emitting layer.

When the trans-1,2-bis(acenyl)ethylene compound is used as a dopant in the light emitting layer, it can be combined with host materials such as, for example, a charge transfer material. The charge transfer material is often a hole transfer material such as an diamine derivative, a triarylamine derivative, or a combination thereof. Exemplary diamine derivatives include, but are not limited to, N,N′-bis(3-methylphenyl)-N,N′-bis(phenyl)benzidine (TPD), N,N′-bis(2-naphthyl)-N,N′-bis(phenyl)benzidine (beta-NPB), and N,N′-bis(1-naphthyl)-N,N′-bis(phenyl)benzidine (NPB). Exemplary triarylamine derivative include, but are not limited to, 4,4′,4″-Tris(N,N-diphenylamino)triphenylamine (TDATA) and 4,4′,4″-Tris(N-3-methylphenyl-N-phenylamino)triphenylamine (MTDATA). Still other host materials include electron transfer materials such as, for example, 9,10-di(2-naphthyl)anthracene (ADN) and oxadiazole compounds such as 1,3-bis[5-(4-(1,1-dimethylethyl)phenyl)-1,3,4-oxadiazol-2-yl]benzene and 2-(biphenyl-4-yl)-5-(4-(1,1-dimethylethyl)phenyl)-1,3,4-oxadiazole.

In other organic emissive elements, the trans-1,2-bis(acenyl)ethylene compound is a host material in a light emitting layer. As used herein, the term “host” refers to a material that is capable of transferring energy to a dopant to form an excited dopant that emits light. The host material is typically present in an amount of at least at least 50 weight percent, at least 60 weight percent, at least 80 weight percent, or at least 90 weight percent based on the weight of material in the light emitting layer.

When the light emitting layer contains a host material and a dopant, the excited state of the host material is typically at a higher energy level than the excited state of the dopant so that energy can be transferred from the host material to the dopant. The excited host material typically emits light of a longer wavelength than the excited dopant. For example, host material that emits blue light can transfer energy to a dopant that emits green or red light and a host material that emits green light can transfer energy to a dopant that emits red light but not to a dopant that emits blue light.

When the trans-1,2-bis(acenyl)ethylene compounds is present in a light emitting layer of an organic emissive element, other light emitting materials can be present in the same light emitting layer or in different light emitting layers. Some light emitting layers have a small molecule (SM) emitter, a small molecule emitter doped polymer, a light emitting polymer (LEP), a small molecule emitter doped light emitting polymer, a blend of light emitting polymers, or a combination thereof. The emitted light from the organic emissive element can be in any portion of the visible spectrum depending on the composition of the electroluminescent composition in the light emitting layer or layers. In some organic emissive elements that contain a trans-1,2-bis(2-acenyl)ethylene compound, blue light can be emitted.

In some embodiments, the organic emissive element has a light emitting layer that contains a light emitting polymer. LEP materials are typically conjugated polymeric or oligomeric molecules that preferably have sufficient film-forming properties for solution processing. As used herein, “conjugated polymers or oligomeric molecules” refer to polymers or oligomers having a delocalized π-electron system along the polymer backbone. Such polymers or oligomers are semiconducting and can support positive and negative charge carriers along the polymeric or oligomeric chain.

Exemplary LEP materials include poly(phenylenevinylenes), poly(para-phenylenes), polyfluorenes, other LEP materials now known or later developed, and co-polymers or blends thereof. Suitable LEPs can also be doped with a small molecule emitter, dispersed with fluorescent dyes or photoluminescent materials, blended with active or non-active materials, dispersed with active or non-active materials, and the like. Examples of suitable LEP materials are further described in Kraft, et al., Angew. Chem. Int. Ed., 37, 402-428 (1998); U.S. Pat. Nos. 5,621,131; 5,708,130; 5,728,801; 5,840,217; 5,869,350; 5,900,327; 5,929,194; 6,132,641; and 6,169,163; and PCT Patent Application Publication No. 99/40655.

LEP materials can be formed into a light emitting structure, for example, by casting a solvent solution of the LEP material on a substrate and evaporating the solvent to produce a polymeric film. Alternatively, LEP material can be formed in situ on a substrate by reaction of precursor species. Suitable methods of forming LEP layers are described in U.S. Pat. No. 5,408,109, incorporated herein by reference. Other methods of forming a light emitting structure from LEP materials include, but are not limited to, laser thermal patterning, inkjet printing, screen printing, thermal head printing, photolithographic patterning, and extrusion coating.

In some embodiments, the organic electroluminescent material can include one or more small molecule emitters. SM electroluminescent materials include charge transporting, charge blocking, and semiconducting organic or organometallic compounds. Typically, SM materials can be vacuum deposited or coated from solution to form thin layers in a device. In practice, multiple layers of SM materials are typically used to produce efficient organic electroluminescent devices since a given material generally does not have both the desired charge transport and electroluminescent properties.

Exemplary SM materials include N,N′-bis(3-methylphenyl)-N,N′-diphenylbenzidine (TPD) and metal chelate compounds such as tris(8-hydroxyquinoline) aluminum (Alq3). Other SM materials are disclosed in, for example, C. H. Chen, et al., Macromol. Symp. 125, 1 (1997); Japanese Laid Open Patent Application 2000-195673; U.S. Pat. Nos. 6,030,715; 6,150,043; and 6,242,115; and PCT Patent Applications Publication Nos. WO 00/18851 (divalent lanthanide metal complexes), WO 00/70655 (cyclometallated iridium compounds and others), and WO 98/55561.

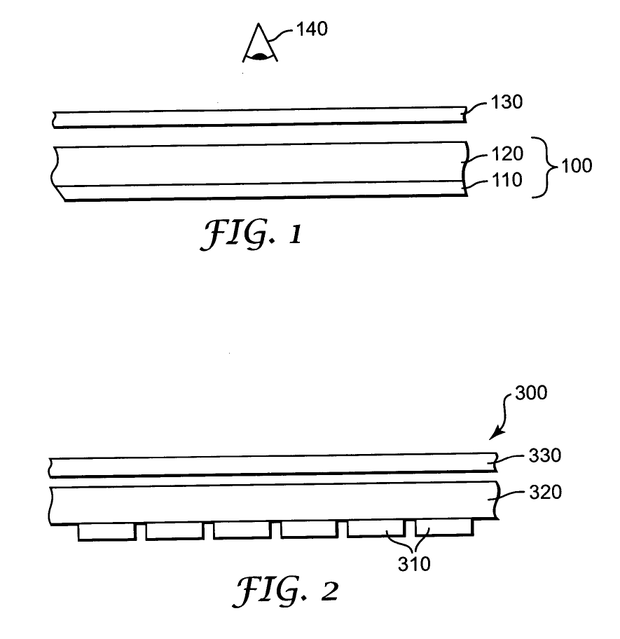

One or more organic electroluminescent devices can be used to form an organic electroluminescent display. FIG. 1 illustrates an OEL display 100 that includes an organic electroluminescent device layer 110 and a substrate 120. Any other suitable display component can also be included with the OEL display 100. Optionally, additional optical elements or other devices suitable for use with electronic displays, devices, or lamps can be provided between display 100 and viewer position 140 as indicated by optional element 130.

In some embodiments like the one shown, OEL device layer 110 includes one or more OEL devices that emit light through the substrate toward a viewer position 140. The viewer position 140 is used generically to indicate an intended destination for the emitted light whether it be an actual human observer, a screen, an optical component, an electronic device, or the like. In other embodiments (not shown), device layer 110 is positioned between substrate 120 and the viewer position 140. The device configuration shown in FIG. 1 (termed “bottom emitting”) may be used when substrate 120 is transmissive to light emitted by device layer 110 and when a transparent conductive electrode is disposed in the device between the light emitting layer of the device and the substrate. The inverted configuration (termed “top emitting”) may be used when substrate 120 does or does not transmit the light emitted by the device layer and the electrode disposed between the substrate and the light emitting layer of the device does not transmit the light emitted by the device. Some devices can have two transparent conductive electrodes and a substrate that is transmissive. Such devices can be transparent and can be both top and bottom emitting.

Device layer 110 can include one or more OEL devices arranged in any suitable manner. For example, in lamp applications (e.g., backlights for liquid crystal display (LCD) modules), device layer 110 might constitute a single OEL device that spans an entire intended backlight area. Alternatively, in other lamp applications, device layer 110 might constitute a plurality of closely spaced devices that can be contemporaneously activated. For example, relatively small and closely spaced red, green, and blue light emitters can be patterned between common electrodes so that device layer 110 appears to emit white light when the emitters are activated. Other arrangements for backlight applications are also contemplated.

In direct view or other display applications, it may be desirable for device layer 110 to include a plurality of independently addressable OEL devices or elements that emit the same or different colors. Each device might represent a separate pixel or a separate sub-pixel of a pixelated display (e.g., high resolution or low resolution displays), a separate segment or sub-segment of a segmented display (e.g., low information content display), or a separate icon, portion of an icon, or lamp for an icon (e.g., indicator applications).

Referring back to FIG. 1, OEL device layer 110 is disposed on substrate 120. Substrate 120 can be any substrate suitable for OEL device and display applications. For example, substrate 120 can include glass, paper, woven or non-woven materials, polymeric, or other suitable material(s) that are substantially transparent to visible light. Suitable substrates can be clear, transparent or translucent, rigid or flexible, filled or unfilled. Substrate 120 can also be opaque to visible light, for example stainless steel, crystalline silicon, amorphous silicon, poly-silicon, or the like. Because some materials in OEL devices can be particularly susceptible to damage due to exposure to oxygen or moisture, substrate 120 preferably provides an adequate environmental barrier, or is supplied with one or more layers, coatings, or laminates that provide an adequate environmental barrier.

Substrate 120 can also include any number of devices or components suitable in OEL devices and displays such as transistor arrays and other electronic devices; color filters, polarizers, wave plates, diffusers, and other optical devices; insulators, barrier ribs, black matrix, mask work and other such components; and the like. Generally, one or more electrodes will be coated, deposited, patterned, or otherwise disposed on substrate 120 before forming the remaining layer or layers of the OEL device or devices of the device layer 110. When a light transmissive substrate 120 is used and the OEL device or devices are bottom emitting, the electrode or electrodes that are disposed between the substrate 120 and the emissive material(s) are preferably substantially transparent to light, for example transparent conductive electrodes such as indium tin oxide (ITO) or any of a number of other transparent conductive oxides.

Element 130 can be any element or combination of elements suitable for use with OEL display or device 100. For example, element 130 can be a LCD module when device 100 is a backlight. One or more polarizers or other elements can be provided between the LCD module and the backlight device 100, for instance an absorbing or reflective clean-up polarizer. Alternatively, when device 100 is itself an information display, element 130 can include one or more of polarizers, wave plates, touch panels, antireflective coatings, anti-smudge coatings, projection screens, brightness enhancement films, or other optical components, coatings, user interface devices, or the like.

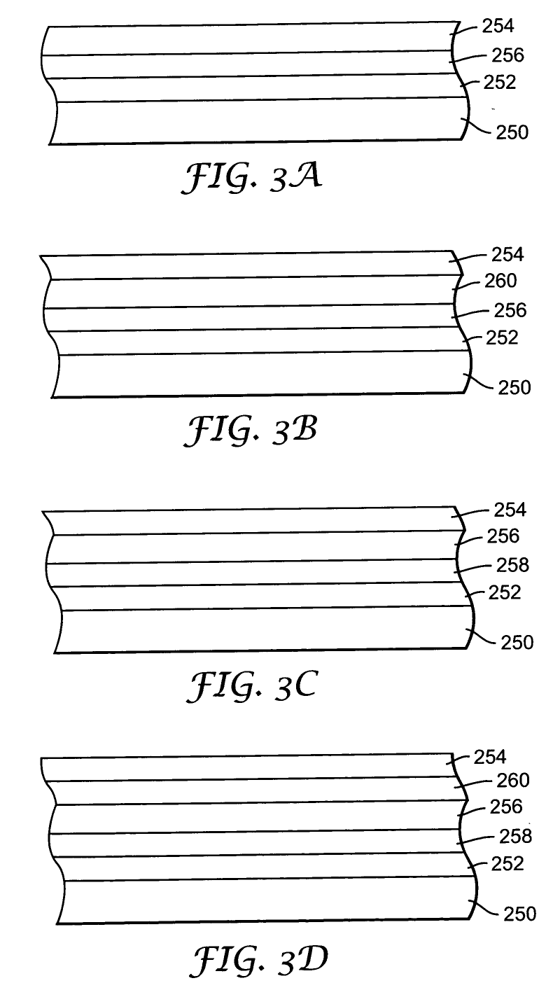

FIGS. 3A to 3D illustrate examples of different OEL device (for example, an organic light emitting diode) configurations of the present invention. Each configuration includes a substrate 250, an anode 252, a cathode 254, and a light emitting layer 256. The light emitting layer 256 can include a compound of Formula I. The configurations of FIGS. 3C and 3D also include a hole transport layer 258 and the configurations of FIGS. 3B and 3D include an electron transport layer 260. These layers conduct holes from the anode or electrons from the cathode, respectively. The compounds of Formula I can be included in one or both of these layers.

The anode 252 and cathode 254 are typically formed using conducting materials such as metals, alloys, metallic compounds, conductive metal oxides, conductive ceramics, conductive dispersions, and conductive polymers, including, for example, gold, silver, nickel, chromium, barium, platinum, palladium, aluminum, calcium, titanium, indium tin oxide (ITO), fluorine tin oxide (FFO), antimony tin oxide (ATO), indium zinc oxide (IZO), poly(3,4-ethylenedioxythiophene)/poly(styrene sulfonate), polyaniline, other conducting polymers, alloys thereof, combinations thereof, and multiple layers thereof. The anode 252 and the cathode 254 can be single layers of conducting materials or they can include multiple layers. For example, an anode or a cathode may include a layer of aluminum and a layer of gold, a layer of calcium and a layer of aluminum, a layer of aluminum and a layer of lithium fluoride, or a metal layer and a conductive organic layer.

A typical anode for an organic electroluminescent device is indium-tin-oxide (ITO) sputtered onto a transparent substrate such as plastic or glass. Suitable substrates include, for example, glass, transparent plastics such as polyolefins, polyethersulfones, polycarbonates, polyesters, polyarylates, and polymeric multilayer films, ITO coated barrier films such as the Plastic Film Conductor available from 3M (St. Paul, Minn.), surface-treated films, and selected polyimides.

The anode material coating the substrate is electrically conductive and may be optically transparent or semi-transparent. In addition to ITO, suitable anode materials include indium oxide, fluorine tin oxide (FTO), zinc oxide, vanadium oxide, zinc-tin oxide, gold, platinum, palladium silver, other high work function metals, and combinations thereof.

Optionally, the anode can be coated with a buffer layer to help provide a flat surface and to modify the effective work function of the anode. The buffer layer typically has a thickness up to 5000 Angstroms, up to 4000 Angstroms, up to 3000 Angstroms, up to 1000 Angstroms, up to 800 Angstroms, up to 600 Angstroms, up to 400 Angstroms, or up to 200 Angstroms. The buffer layer often has a thickness of at least 5 Angstroms, at least 10 Angstroms, or at least 20 Angstroms. The buffer layer can be vapor coated or solution coated.

Suitable buffer layers can be an ionic polymer such as poly(3,4-oxyethyleneoxy thiophene)/poly(styrene sulfonate), polyaniline emeraldine, or an acid doped polypyrrole. Other suitable buffer layers include those described in U.S. patent application No. 2004/0004433A1, incorporated herein by reference, that include (a) a hole transport material having triarylamine moieties and (b) an electron acceptor material. Suitable hole transport material can be a small molecule or a polymeric material. Exemplary hole transport material include, but are not limited to, 4,4′,4″-tris(N,N-diphenylamino)triphenylamine (TDATA), 4,4′,4″-tris(N-3-methylphenyl-N-phenylamino)triphenylamine (MTDAA), 4,4′,4″-tris(carbozole-9-yl)triphenylamine (TCTA), and 4,4′,4″-tris(N-naphthyl)-N-phenylamino)triphenylamine (2-TNATA). Exemplary electron transport materials that can be included in such a buffer layer include, but are not limited to, tetracyanoquinodimethane (TCNQ), tetafluoro-tetracynaoquinodimethan, tetracyanoethylene, chloranil, 2-(4-(1-methylethyl)phenyl-6-phenyl-4H-thiopyran-4-ylidene)-propanedinitrile-1,1-dioxyide (PTYPD), and 2,4,7-trinitrofluorene.

Typical cathodes include low work function metals such as aluminum, barium, calcium, samarium, magnesium, silver, magnesium/silver alloys, lithium, lithium fluoride, ytterbium, and of calcium/magnesium alloys. The cathode can be a single layer or multiple layers of these materials. For example, the cathode can include a layer of lithium fluoride, a layer of aluminum, and a layer of silver.

The hole transport layer 258 facilitates the injection of holes from the anode into the device and their migration towards the recombination zone. The hole transport layer 258 can further act as a barrier for the passage of electrons to the anode 252. In some examples, the hole transport layer 258 can include, for example, a diamine derivative, such as N,N′-bis(3-methylphenyl)-N,N′-bis(phenyl)benzidine (TPD), N,N′-bis(2-naphthyl)-N,N′-(bis(phenyl)bizidine (beta-NPB), and N,N′-bis(1-naphthyl)-N,N′-bis(phenyl)benzidine (NPB); or a triarylamine derivative, such as, 4,4′,4″-tris(N,N-diphenylamino)triphenylamine (TDATA), 4,4′,4″-tris(N-3-methylphenyl-N-phenylamino)triphenylamine (MTDATA), 4,4′,4″-tri(N-phenoxazinyl) triphenylamine (TPOTA), and 1,3,5-tris(4-diphenylaminophenyl)benzene (TDAPB).

The electron transport layer 260 facilitates the injection of electrons from the cathode into the device and their migration towards the recombination zone. The electron transport layer 260 can further act as a barrier for the passage of holes to the cathode 254. In some examples, the electron transport layer 260 can be formed using the organometallic compound such as tris(8-hydroxyquinolato) aluminum (Alq3) and biphenylato bis(8-hydroxyquinolato)aluminum (BAlq). Other examples of electron transport materials useful in electron transport layer 260 include 1,3-bis[5-(4-(1,1-dimethylethyl)phenyl)-1,3,4-oxadiazol-2-yl]benzene; 2-(biphenyl-4-yl)-5-(4-(1,1-dimethylethyl)phenyl)-1,3,4-oxadiazole; 9,10-di(2-naphthyl)anthracene (ADN); 2-(4-biphenyl)-5-(4-t-butylphenyl)-1,3,4-oxadiazole; or 3-(4-biphenylyl)4-phenyl-5-(4-tert-butylphenyl)-1,2,4-triazole (TAZ).

Other layers such as, for example, additional hole injection layers containing, for example, porphyrinic compounds like copper phthalocyanine (CuPc) and zinc phthalocyanine; electron injection layers containing, for example, alkaline metal oxides or alkaline metal salts; hole blocking layers containing, for example, molecular oxadiazole and triazole derivatives such as 2-(4-biphenyl)-5-(4-t-butylphenyl)-1,3,4-oxadiazole (PBD), 2,9-dimethyl-4,7-diphenyl-1,10-phenanthraline (BCP), biphenylato bis(8-hydroxyquinolato)aluminum (BAlq), or 3-(4-biphenylyl)-4-phenyl-5-(4-tert-butylphenyl)-1,2,4-triazole (TAZ); electron blocking layers containing, for example, N,N′-bis(1-naphthyl)-N,N′-bis(phenyl) benzidine (NPB), or 4,4′,4″-tris(N-(3-methylphenyl)-N-phenylamino)triphenylamine (MTDATA); or the like can also be present in organic emissive element. In addition, photoluminescent materials can be present in these layers, for example, to convert the color of light emitted by the electroluminescent material to another color. These and other such layers and materials can be used to alter or tune the electronic properties and behavior of the layered OEL device, for example, to achieve one or more features such as a desired current/voltage response, a desired device efficiency, a desired color, a desired brightness, a desired device lifetime, or a desired combination of these features.

In some applications, the organic electroluminescent device can emit blue light. In other applications, the organic emissive element includes multiple light emitting layers and the organic electroluminescent device can emit white light.

In one embodiment, OEL displays can be made that emit light and that have adjacent devices or elements that can emit light having different color. For example, FIG. 2 shows an OEL display 300 that includes a plurality of OEL elements 310 adjacent to each other and disposed on a substrate 320. Two or more adjacent elements 310 can be made to emit different colors of light, for example red, green, and blue. One or more of elements 310 include a compound according to Formula I.

The separation shown between elements 310 is for illustrative purposes only. Adjacent devices may be separated, in contact, overlapping, etc., or different combinations of these in more than one direction on the display substrate. For example, a pattern of parallel striped transparent conductive anodes can be formed on the substrate followed by a striped pattern of a hole transport material and a striped repeating pattern of red, green, and blue light emitting layers, followed by a striped pattern of cathodes, the cathode stripes oriented perpendicular to the anode stripes. Such a construction may be suitable for forming passive matrix displays. In other embodiments, transparent conductive anode pads can be provided in a two-dimensional pattern on the substrate and associated with addressing electronics such as one or more transistors, capacitors, etc., such as are suitable for making active matrix displays. Other layers, including the light emitting layer(s) can then be coated or deposited as a single layer or can be patterned (e.g., parallel stripes, two-dimensional pattern commensurate with the anodes, etc.) over the anodes or electronic devices. Any other suitable construction is also contemplated by the present invention.

In one embodiment, display 300 in FIG. 2 can be a multiple color display. In exemplary embodiments, each of the elements 310 emits light. There are many displays and devices constructions covered by the general construction illustrated in FIG. 2. Some of those constructions are discussed as follows.

Constructions of OEL backlights can include bare or circuitized substrates, anodes, cathodes, hole transport layers, electron transport layers, hole injection layers, electron injection layers, emissive layers, color changing layers, and other layers and materials suitable in OEL devices. Constructions can also include polarizers, diffusers, light guides, lenses, light control films, brightness enhancement films, and the like. Applications include white or single color large area single pixel lamps as well as white or single color large area single electrode pair lamps with a large number of closely spaced emissive layers.

Constructions of low resolution OEL displays can include bare or circuitized substrates, anodes, cathodes, hole transport layers, electron transport layers, hole injection layers, electron injection layers, emissive layers, color changing layers, and other layers and materials suitable in OEL devices. Constructions can also include polarizers, diffusers, light guides, lenses, light control films, brightness enhancement films, and the like. Applications include graphic indicator lamps (e.g., icons); segmented alphanumeric displays (e.g., appliance time indicators); small monochrome passive or active matrix displays; small monochrome passive or active matrix displays plus graphic indicator lamps as part of an integrated display (e.g., cell phone displays); large area pixel display tiles (e.g., a plurality of modules, or tiles, each having a relatively small number of pixels), such as may be suitable for outdoor display used; and security display applications.

Constructions of high resolution OEL displays can include bare or circuitized substrates, anodes, cathodes, hole transport layers, electron transport layers, hole injection layers, electron injection layers, emissive layers, color changing layers, and other layers and materials suitable in OEL devices. Constructions can also include polarizers, diffusers, light guides, lenses, light control films, brightness enhancement films, and the like. Applications include active or passive matrix multicolor or full color displays; active or passive matrix multicolor or full color displays plus segmented or graphic indicator lamps and security display applications.

In another aspect of the invention, a method of preparing an organic electroluminescent device is provided. The method involves preparing an organic emissive element that contains a trans-1,2-bis(acenyl)ethylene compound of Formula I; and positioning the organic emissive element between two electrodes.

In some embodiments of this method, the organic emissive element has multiple layers of material. For example, the organic emissive element can be prepared by depositing a light emitting layer that contains a trans-1,2-bis(acenyl)ethylene compound of Formula I; and depositing a second layer adjacent to the light emitting layer. The second layer can be a charge transport layer, a charge blocking layer, a charge injection layer, a buffer layer, or a combination thereof. One exemplary organic electroluminescent device includes, in the following order, an anode, a hole transport layer, a light emitting layer, an electron transport layer, and a cathode.

The organic emissive element is often prepared by vapor deposition techniques. That is, the trans-1,2-bis(2-acenyl)ethylene compounds can be formed using vapor deposition techniques. Other suitable methods of preparing the organic emissive element include, but are not limited to, thermal transfer, inkjet printing, gravure printing, shadow masking, lithography, microcontact printing, and screen printing.

### EXAMPLES

Objects and advantages of this invention are further illustrated by the following examples, but the particular materials and amounts thereof recited in these examples, as well as other conditions and details, should not be construed to unduly limit this invention.

Anhydrous N,N-dimethylformamide (DMF), anhydrous 1,4-dioxane, anhydrous chlorobenzene, cyclohexanol, and aluminum tri-sec-butoxide were purchased from Aldrich (Milwaukee, Wis.).

Pd₂(dba)₃ (dba=dibenzylideneacetone), tetrakis(triphenylphosphine)palladium(0) (Pd(PPh₃)₄), tri-tert-butylphosphine (P(t-Bu)₃) (10 weight percent in hexanes), and CsF were purchased from Strem Chemicals (Newburyport, Mass.). Cesium fluoride (CsF) was ground to a fine powder, dried under vacuum at 100° C. for several hours, and stored in a dry box.

Trans-1,2-bis(tri-n-butylstannyl)ethylene, 4-bromophthalic anhydride, and 2,3-naphthalic anhydride were purchased from TCl America (Portland, Oreg.).

Trifluoromethanesulfonic acid (triflic acid) was obtained from 3M Company (St. Paul, Minn.) under the trade designation “FLUORORAD FC 24”.

Trifluoromethanesulfonic anydride was purchased from Matrix Scientific (Columbia, S.C.).

### Preparatory Example 1

### Synthesis of 2-bromoanthracene (Formula XIII)

2-bromoanthracene (Formula XIII) was prepared as shown in Reaction Scheme C.

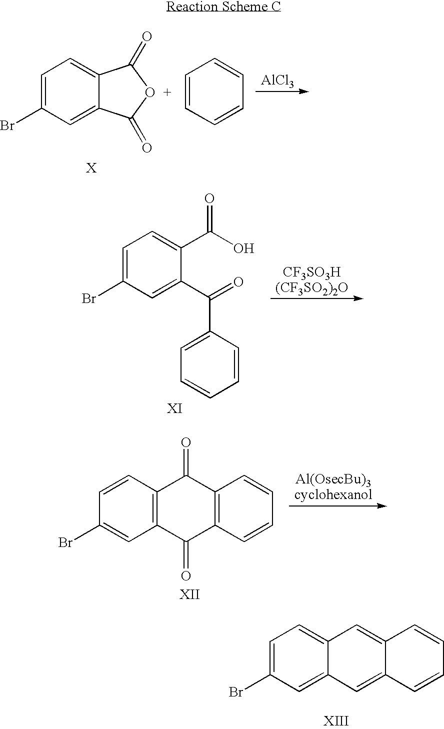

### 2-benzoyl-4(5)-bromobenzoic acid (Formula XI)

A 1 L, 3-necked flask was charged with benzene (300 mL) and AlCl₃ (73.4 g). The suspension was cooled with an ice water bath and 4-bromophthalic anhydride (Formula X, 50 g) was gradually added. The mixture was heated to 65° C. for 4 hours, then poured into a large beaker containing 1500 mL of crushed ice. The solution was stirred and mixed with diethyl ether (1 L) and concentrated hydrochloric acid (HCI) (100 mL) to dissolve all solids. The organic phase was separated and washed three times with 200 mL brine, dried with MgSO₄, and filtered. The volatiles were stripped under reduced pressure and the solid were dried under vacuum overnight to afford 60.0 g (89 percent yield) of white product. DSC data: 144° C., 169° C. (unresolved peaks), ΔH=139 Jg⁻¹. ¹H NMR analysis showed a complex series of multiplets from about 7.4 to 8.2 ppm. A molecular ion at 306 Daltons was observed using electron impact mass spectroscopy (EIMS).

### 2-bromoanthraquinone (Formula XII)

2-Benzoyl-4(5)-bromobenzoic acid (Formula XI, 11.2 g) was gradually added to a strirred solution of trifluoromethanesulfonic acid (80 mL) and trifluoromethanesulfonic anhydride (9.2 mL). The red mixture was stirred at 75° C. for 4 hours, then cooled and poured into 300 mL of crushed ice. The off-white solid was collected on a filter frit (25-50 μm pores), washed four times with 100 mL water, and dried under vacuum to afford 9.84 g (94 percent yield) of product. DSC data (scanned at 20° C./min): peak temp of 210° C. (ΔH=173 Jg⁻¹); literature melting point values are in the range 204° C. to 211° C. Spectroscopic data (IR, NMR) were consistent with other literature values. IR (KBr pressed pellet): v_{CO}=1678 cm⁻¹.

### 2-bromoanthracene (Formula XII)

2-bromoanthraquinone (Formula XII, 35.2 g) was added to a 3-L, 3-necked flask fitted with a distillation head and receiver. The system was put under a N₂ blanket and charged with cyclohexanol (1 L), and Al(O-sec-Bu)₃ (375 mL). The mixture was heated until distillate began collecting in the receiver at a pot temperature of about 120° C. The distillation was continued until the pot temperature reached 162° C., and then cooled to 155° C. The reaction was stirred at 155° C. over 48 h, then cooled to 100° C. and poured into a large beaker containing methanol (MeOH) (1 L), water (400 mL) and concentrated HCl (200 mL). The off-white precipitate was collected on a filter frit (40-60 μm pores), washed with water (30 mL) and MeOH (1 L), and air-dried overnight. The product was dried further under vacuum to afford 22.4 g (71 percent yield). DSC data (scanned at 20° C./min): peak temp 220° C., ΔH=126 Jg⁻¹. IR (KBr, strong abs only): 892, 741, 474 cm⁻¹. ¹H NMR (500 MHz, d₆-Me₂SO): δ 7.56 (m, 6 lines, 6-H, 8-H), 7.60 (dd, J =2.0, 9.0 Hz, 7-H), 8.09 (m, 1-H, 3-H, 4-H), 8.39 (‘d’, J=1 Hz, 9-H), 8.57 (s, 5-H), 8.63 (s, 10-H).

### Preparatory Example 2

### Synthesis of 2-chlorotetracene (Formula XVII)

2-chlorotetracene (Formula XVII) was prepared as shown in Reaction Scheme D.

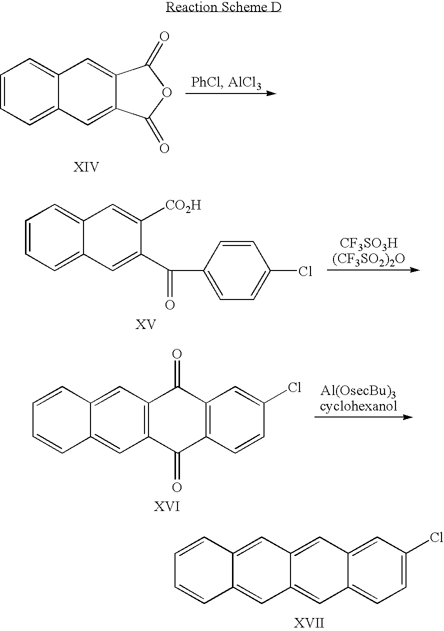

### 3-(4-chlorobenzoyl)-naphthalene-2-carboxylic acid (Formula XV)

A 500 mL, 3-necked flask fitted with a water condenser and gas adapter, was purged with nitrogen, and charged with AlCl₃ (61 g) and chlorobenzene (400 mL). The mixture was cooled with an ice water bath and 2,3-naphthalic anhydride (Formula XIV, 40.9 g) was gradually added. The mixture, which was heated at 65° C. for 4.5 hours, turned deep red. The solution was poured into a 4 L beaker containing 1 L of crushed ice, followed by concentrated HCl (100 mL), ethyl acetate (1 L), and diethyl ether (500 mL). The organic phase was separated from the aqueous phase and split into three equal portions. Each portion was successively extracted with 300 mL of 0.3 M NaOH (aq) and then 225 mL of 0.2 M NaOH (aq). The combined basic extracts from all portions (about 1.6 L) was stirred rapidly with crushed ice and acidified by adding concentrated HCl dropwise until the pH was 1. The precipitate that formed was isolated on a filter frit and air dried overnight to afford 53.8 g (84 percent yield) of white product. Mass spectrometry of a methylated sample showed the desired product accounting for more than 99 percent of the total ion current. No de-chlorinated product was detected as an impurity. ¹H NMR (400 MHz, d₆-Me₂SO): δ 7.58 (‘dt’ J=2.0, 8.8 Hz, 2 H), 7.70 (‘dt’, J=1.6, 8.4 Hz, 2 H), 7.75 (m, 2H), 8.05 (s, 1 H), 8.10 (m, 1 H), 8.23 (m, 1 H), 8.67 (s, 1 H).

### 2-chloro-5,12-tetracenequinone (Formula XVI)

A 500 mL flask was successively loaded with trifluoromethanesulfonic acid (175 mL), 3-(4-chlorobenzoyl)-naphthalene-2-carboxylic acid (Formula XV, 25.5 g), and trifluoromethanesulfonic anhydride (21 mL). The mixture was heated at 155° C. for 10 hours. The violet-blue solution was gradually poured into a 2 L beaker containing 1 L of crushed ice. Additional ice was added as necessary to keep the solution cold. The brown-green mixture was poured onto a large 25-50 μm glass frit, and the isolated solid was washed with water (1 L), methanol (300 mL), and then air-dried overnight. The crude material was purified by high vacuum train sublimation (less than 10⁻³ Torr) at a source temperature of 165° C. to afford 17.5 g (73 percent yield) of bright yellow product. ¹H NMR (400 MHz, d₆-DMSO): δ 8.89 (‘s’, 6-H and 11-H), 8.36 (m, 4 lines, J=3.2 Hz, 7-H and 10-H), 8.30 (‘d’, J=8 Hz, 4-H), 8.22 (‘d’, 2 Hz, 1-H), 8.02 (‘dd’, J=2 Hz, 4 Hz), 7.82 (m, 4 lines, J=3.2 Hz, 8-H and 9-H).

### 2-chlorotetracene (Formula XVII)

A 3-necked, 2 L round-bottomed vessel was fitted with a distillation head and receiver, and purged with nitrogen. 2-chloro-5,12-tetracenequinone (Formula XVI, 20 g), cyclohexanol (400 mL), and Al(O-sec-Bu)₃ (210 mL) were successively charged. The mixture was heated until distillate began collecting in the receiver at a pot temperature of about 120° C. The distillation was continued until the pot temperature reached 162° C., and then cooled to 155° C. A bright orange precipitate formed as the reaction stirred at 155° C. over 72 hours. The mixture was cooled to 120° C., and gradually poured into a stirred mixture of methanol (350 mL), water (200 mL), and concentrated HCl (100 mL). A bright orange solid was isolated on a 25-50 μm glass frit, washed twice with 200 mL methanol, and dried under vacuum overnight. The crude material (12.1 g) was purified by vacuum train sublimation at 4×10⁻⁶ Torr and a source temperature of 260° C. to afford 11.4 g (64%) of bright orange product. DSC (under nitrogen, scanned at 20° C./min): 361° C. (ΔH=96 Jg⁻¹, decomp). EIMS: 262 ([M]+, 100%), 226 ([M-HCl]+, 23%). Anal. Calcd. for C₁₈H₁₁Cl: C, 82.3; H, 4.22. Found: C, 82.5; H, 4.27.

### Example 1

### Synthesis of trans-1,2-bis(2-anthracenyl)ethylene (Formula I where both Ac¹ and Ac² are anthracenyl)

Under a nitrogen atmosphere, a vessel was successively charged with Pd(PPh₃)₄ (58 mg), 2-bromoanthracene (Formula XIII, 857 mg), dry DMF (20 mL), and trans-1,2-bis(tri-n-butylstannyl)ethylene (1.01 g). The mixture was warned with an 84° C. oil bath and became clear yellow. A yellow precipitate formed in the mixture as it was stirred overnight. The vessel was cooled and the solids were collected on a glass filter frit (10-20 μm pores), washed three times with water (25 mL), and air-dried overnight. The crude product was train sublimed under vacuum (10⁻⁵-10⁻⁶ Torr) at a source temperature of 275° C. A bright yellow product (470 mg, 74 percent yield) was collected from the middle zone (200° C.). The material was sublimed a second time (greater than 90 percent recovery) prior to device fabrication.

Analysis of the synthesized material by thermal desorption electron ionization mass spectroscopy (EIMS) was completed using a Micromass Quatroll triple quadrupole mass spectrometer. A few micorgrams of a sample were placed into a quartz sample vial that was heated from 50-650° C. over 15 minutes. The mass spectrometer was tuned to unit mass resolution and scanned from m/z 100 to 620 amu. The positive ion mass spectrum showed evidence for the desired product only (380 amu).

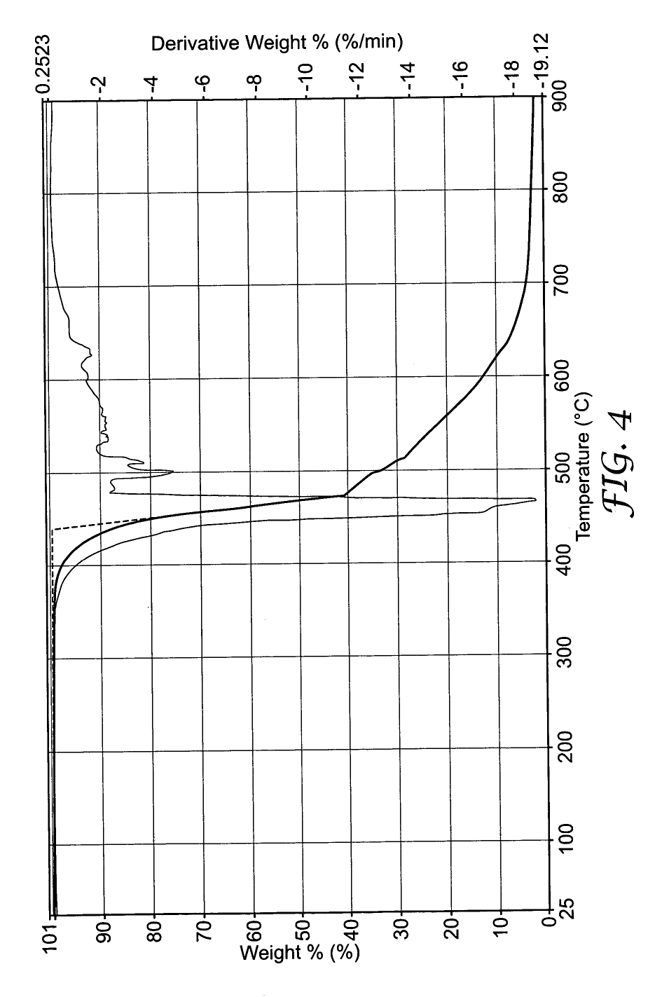

FIG. 4 shows a plot of thermal gravimetric analysis (TGA) data obtained for a sample of trans-1,2-bis-(2-anthracenyl)ethylene powder. The experiment was run under a nitrogen atmosphere and scanned from 25° C. to 900° C. at 10° C./min. The plotted data shows that the material is stable up to about 400° C.

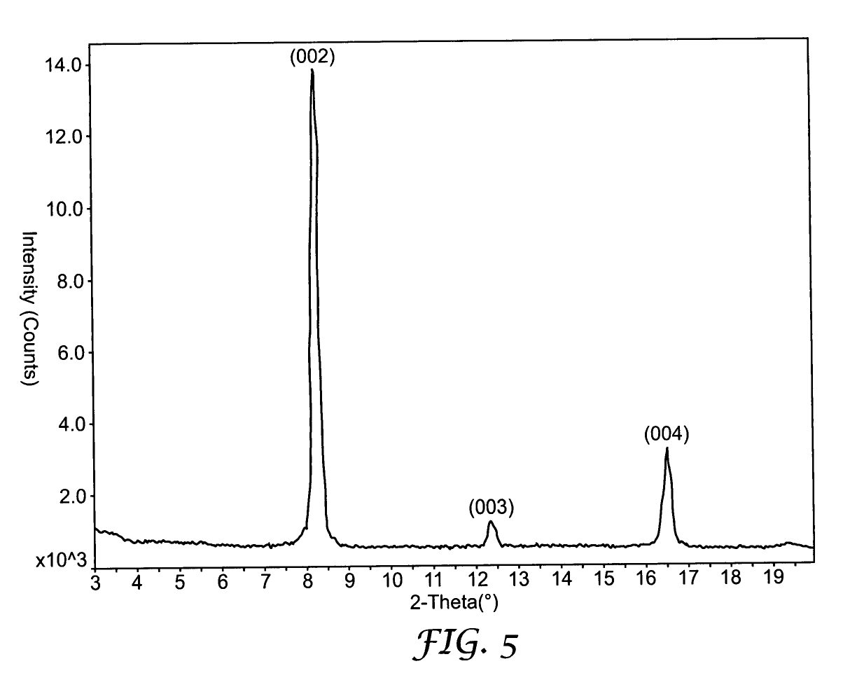

Thin films (e.g., thickness of about 30 nm) of trans-1,2-bis(2-anthracenyl)ethylene were vapor deposited and analyzed using X-ray diffraction (Cu Kα radiation). Reflection geometry survey scans were collected by use of a Philips vertical diffractometer, and proprotional detector registry of the scattered radiation. The diffractometer was fitted with variable incident beam slits, fixed diffracted beam slits, and graphite diffracted beam monochromator. The survey scans were conducted from 3 to 40 degrees (2θ) using a 0.04 degree step size and 6 second dwell time. X-ray generator settings of 45 kV and 35 mA were employed. A representative diffraction pattern of trans-1,2-bis(2-antracenyl)ethylene adsorbed on a poly(α-methyl styrene) (AMS) coated SiO₂ substrate is shown in FIG. 5. The sample had a series of (0,0,1) reflections that are consistent with a lamellar structure. The interlayer spacing of 24.5 Å corresponds closely to the extended molecular length, and suggests that the molecules are oriented about perpendicular to the substrate plane.

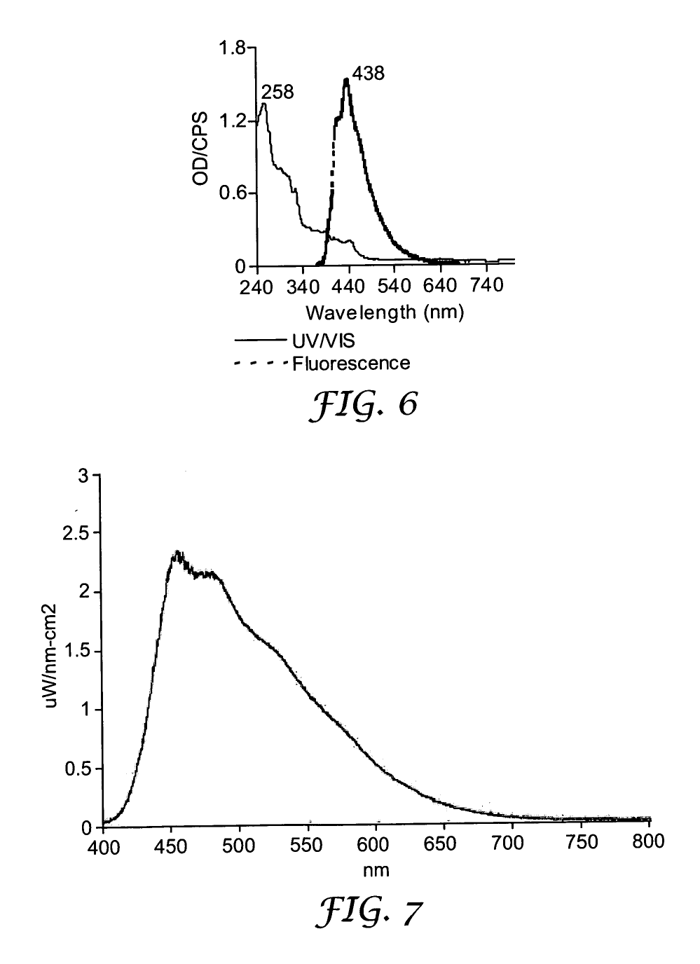

FIG. 6 shows the ultraviolet-visible adsorption spectra and the fluorescence spectra for trans-1,2-bis(2-anthracenyl)ethylene. The ultraviolet-visible adsorption spectra was recorded using a saturated solution of trans-1,2-bis(2-anthracenyl)ethylene in methylene chloride (e.g., trans-1,2-bis(2-anthracenyl)ethylene is only sparingly soluble in methylene chloride). The saturated solution was further diluted with methylene chloride to record the fluorescence spectra. The intensities of both spectra were normalized for plotting. The fluorescence is in the blue region of the visible spectrum at about 438 nm.

### Example 2

### Synthesis of trans-1,2-bis(2-tetracenyl)ethylene (Formula I where Ac¹ and Ac² are tetracenyl)

Under nitrogen, a 100 mL vessel was successively charged with Pd₂(dba)₃ (45 mg), CsF (1.1 g), 1,4-dioxane (30 mL), trans-1,2-bis(tri-n-butylstannyl)ethylene (975 mg), 2-chlorotetracene (Formula XVII, 840 mg), and P(tert-Bu)₃ (0.6 mL of 10 wt % hexanes solution). The mixture was stirred and purged through with a nitrogen stream for 30 min. The mixture was stirred and heated with an oil bath (85° C.) for 3 days, cooled, and poured through a 10-15 μm filter frit to isolate a deep red precipitate. The material was washed with 25 mL of water and air dried overnight. Vacuum train sublimation at 1×10⁻⁴ Torr and a source temp of 475° C. afforded 218 mg (10 percent yield) of red product. From the coolest zone of the sublimation was isolated 215 mg of 2-chlorotetracene starting material (26 percent of the reactant), indicating that the reaction conditions were not optimized.

A sample of the product was suspended in THF and mixed with a solution of 2-(4-hydroxyphenylazo)benzoic acid (HABA). Matrix assisted laser desorption ionization mass spectra were recorded using an Applied Biosystems Voyager DE STR MALDI/TOF instrument operated in the reflection mode. A molecular species was detected at 480 Da.

### Example 3

### Device Preparation and Testing

Several organic light-emitting diodes (OLEDS) were prepared on 22 mm square (1 mm thick) indium-tin oxide (ITO) coated glass substrates (20 ohm/square, available from Colorado Concept Coatings LLC, Longmount, Co.). The substrates were cleaned by initially rubbing the ITO surface with a methanol-soaked lint-free cloth (VECTRA ALPHA 10, available from Texwipe Co., LLC, Upper Saddle River, N.J.) and then treating the surface with an oxygen plasma for 4 minutes. The plasma, available from Plasmatic Systems, Inc., North Brunswick, N.J. under the trade designation PLASMA-PREEN II-973, was operated at full power with 5 psi oxygen gas.

An aqueous solution of polythiophene (1% solids, BAYTRON P 4083, available from Bayer, Luverkuesen, Germany) was spin coated onto the substrates at 2500 rpm for 30 seconds using a bench top spin coater (Model WS-400A-6NPP-Lite, available from Laurell Technologies Corp., North Wales, Pa.). The polythiophene-coated substrates were dried at 110° C. under a nitrogen flow for 10 minutes. They were then placed in a bell jar OLED fabrication chamber over stainless steel shadow masks with 19.5×19.5 mm openings centered in the 22×22 mm masks. The chamber was evacuated to about 5×10⁻⁶ Torr and a partial OLED stack was deposited by sequential thermal evaporation from quartz crucibles as follows: N,N′-bis(1-naphthyl)-N,N′-bis(phenyl)benzidine (NPB) (400 Å at 1 Å/sec); 9,10-di(2-naphthyl)anthracene (ADN) doped with 1 to 2 weight percent 1,2-bis(2-anthracenyl)ethylene (300 Å at 1 Å/sec); and tris(8-hydroxyquinolato) aluminum (Alq3) (200 Å at 1 Å/sec). The NPB was the hole transport layer and the Alq3 was the electron transport layer.

The vacuum was broken and the partial devices were transferred using a vacuum desiccator to minimize air exposure into a glove box that contained a thin film evaporation chamber (available from BOC Edwards, England under the trade designation EDWARDS 500) for thermal deposition of cathodes. Tris(8-hydroxyquinolato) aluminum (Alq3) (300 Å at about 1.6 Å/sec), lithium fluoride (7 Å at about 0.5 Å/sec), aluminum (200 Å at about 1.0 Å/sec), and silver (1000 Å at about 2.5 Å/sec) were sequentially deposited at about 2×10⁻⁷Torr onto the NPB/ADN: 1,2-bis(2-anthracenyl)ethylene/Alq3 coated substrates through metal shadow masks with 1 cm² circular openings centered in the 22×22 mm masks.

After venting and removal from the deposition chamber, the completed devices showed emission of blue light when driven at 6-8 volts. FIG. 7 shows a plot of light intensity versus wavelength for the OLED.

We claim:

1. An organic electroluminescent device comprising two electrodes and an organic emissive element positioned between the two electrodes, said electroluminescent layer comprising a trans-1,2-bis(acenyl)ethylene compound of Formula I 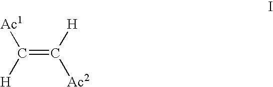
wherein
each Ac¹ and Ac² is independently a 2-acenyl selected from 2-naphthyl, 2-anthracenyl, or 2-tetracenyl, said 2-acenyl being unsubstituted or substituted with an alkyl, alkoxy, alkylthio, halo, haloalkyl, or a combination thereof.

2. The organic electroluminescent device of claim 1, wherein the Ac¹ and Ac² groups are identical.

3. The organic electroluminescent device of claim 1, wherein the Ac¹ and Ac² groups are unsubstituted.

4. The organic electroluminescent device of claim 1, wherein the compound of Formula I is substituted or unsubstituted trans-1,2-bis(2-naphthyl)ethylene; substituted or unsubstituted trans-1,2-bis(2-anthracenyl)ethylene; or substituted or unsubstituted trans- 1,2-bis(2-tetracenyl)ethylene.

5. The organic electroluminescent device of claim 1, wherein the compound of Formula I is substituted or unsubstituted trans-1,2-bis(2-anthracenyl)ethylene.

6. The organic electroluminescent device of claim 1, wherein the organic emissive element comprises a light emitting layer comprising the trans-1,2-bis(acenyl)ethylene compound.

7. The organic electroluminescent device of claim 1, wherein the organic emissive element comprises multiple layers and wherein the trans-1,2-bis(acenyl)ethylene compound is in a light emitting layer, a charge transporting layer, or a combination thereof.

8. The organic electroluminescent device of claim 1, wherein the organic emissive element comprises a light emitting layer comprising (a) a host material and (b) a dopant comprising the trans-1,2-bis(acenyl)ethylene compound.

9. The organic electroluminescent device of claim 6, wherein the light emitting layer emits blue light.

10. A method of preparing an organic electroluminescent device, said method comprising:
preparing an organic emissive element comprising a trans-1,2-bis(acenyl)ethylene compound of Formula I 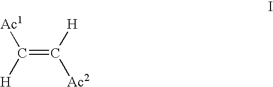
wherein each Ac¹ and Ac² is independently a 2-acenyl selected from 2-naphthyl, 2-anthracenyl, or 2-tetracenyl, said 2-acenyl being unsubstituted or substituted with an alkyl, alkoxy, alkylthio, halo, haloalkyl, or a combination thereof; and
positioning the organic emissive element between two electrodes.

11. The method of claim 10, wherein the compound of Formula I is substituted or unsubstituted trans-1,2-bis(2-naphthyl)ethylene; substituted or unsubstituted trans-1,2-bis(2-anthracenyl)ethylene; or substituted or unsubstituted trans-1,2-bis(2-tetracenyl)ethylene.

12. The method of claim 10, wherein the compound of Formula I is substituted or unsubstituted trans-1,2-bis(2-antracenyl)ethylene.

13. The method of claim 10, wherein said preparing of the organic emissive element comprises vapor depositing the trans-1,2-bis(acenyl)ethylene compound.

14. The method of claim 10, wherein said preparing of the organic emissive element comprises vapor depositing (a) a host material and (b) a dopant comprising the trans-1,2-bis(acenyl)ethylene compound.

15. The method of claim 14, wherein the host material comprises a hole transfer material.

16. The method of claim 10, wherein said preparing of the organic emissive element comprises forming a light emitting layer comprising the trans-1,2-bis(acenyl)ethylene compound.

17. The method of claim 16, wherein said preparing of the organic emissive element further comprises depositing a second layer between the light emitting layer and at least one of the electrodes, said second layer comprising a charge blocking layer, a charge transport layer, a charge injection layer, a buffer layer, or a combination thereof.

18. The method of claim 10, wherein said preparing of the organic emissive element comprises forming multiple layers selected from a light emitting layer, a charge blocking layer, a charge transport layer, a charge injection layer, a buffer layer, or a combination thereof.

19. The method of claim 18, wherein the trans-1,2-bis(acenyl)ethylene compound is in the light emitting layer, the charge transport layer, or a combination thereof.

20. The method of claim 10, wherein the organic electroluminescent device is an organic light emitting diode.
